(19) United States
(12) Patent Application Publication
(10) Pub. No.: US 2024/0282823 A1
(43) Pub. Date: Aug. 22, 2024

(54) POWER SEMICONDUCTOR DEVICE

(71) Applicant: HYUNDAI MOBIS CO., LTD., Seoul (KR)

(72) Inventor: Ju Hwan LEE, Yongin-si (KR)

(73) Assignee: HYUNDAI MOBIS CO., LTD., Seoul (KR)

(21) Appl. No.: 18/508,706

(22) Filed: Nov. 14, 2023

(30) Foreign Application Priority Data
Feb. 16, 2023 (KR) 10-2023-0020741

(51) Int. Cl. H01L 29/16; H01L 29/06; H01L 29/10; H01L 29/423; H01L 29/66

(52) U.S. Cl. CPC H01L 29/1608; H01L 29/0619; H01L 29/1095; H01L 29/42364; H01L 29/66893

(57) ABSTRACT

A power semiconductor device including a semiconductor layer having a first conductivity type and configured to include a protrusion formed from an upper region of the semiconductor layer to partially protrude upward, a shielding region having a second conductivity type opposite to the first conductivity type and disposed within the protrusion and configured to contact a top surface of the protrusion, a gate insulation layer disposed on the semiconductor layer and configured to cover the protrusion and to come into contact with the shielding region, and a gate electrode layer disposed on the gate insulation layer.

### CROSS-REFERENCE TO RELATED APPLICATION

This application claims the benefit under 35 USC § 119(a) of Korean Patent Application No. 10-2023-0020741, filed in the Korean Intellectual Property Office on Feb. 16, 2023, the entire disclosure of which is incorporated herein by reference for all purposes.

### BACKGROUND

### 1. Field

Embodiments of the present disclosure relate to a semiconductor device, and more particularly, to a power semiconductor device for switching power transmission.

### 2. Description of the Related Art

A power semiconductor device is a semiconductor device operating in a high voltage and high current environment. The power semiconductor device is used in fields requiring high power switching, for example, power conversion systems, power converters, inverters, etc. For example, the power semiconductor device may include an insulated gate bipolar transistor (IGBT), a power MOSFET, and the like. The power semiconductor device basically requires withstand characteristics for high voltage, and recently, additionally, a high-speed switching operation.

Accordingly, research on power semiconductor devices using silicon carbide (SiC) instead of conventional silicon (Si) has been conducted. Silicon carbide (SiC) is a wide-gap semiconductor material with a higher band gap than silicon, and can maintain stability even at high temperature compared to silicon. Furthermore, since silicon carbide has a very high dielectric breakdown field compared to silicon, silicon carbide can stably operate even at high voltage compared to silicon. Therefore, silicon carbide has a higher breakdown voltage than silicon and excellent heat dissipation so that the silicon carbide can operate at high temperature.

In order to increase the channel density of a power semiconductor device using silicon carbide (SiC), a trench-type gate structure having a vertical channel structure has been intensively researched and proposed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a power semiconductor device including a semiconductor layer having a first conductivity type and configured to include a protrusion formed from an upper region of the semiconductor layer to partially protrude upward, a shielding region having a second conductivity type opposite to the first conductivity type and disposed within the protrusion and configured to contact a top surface of the protrusion, a gate insulation layer disposed on the semiconductor layer and configured to cover the protrusion and to be in contact with the shielding region, and a gate electrode layer disposed on the gate insulation layer.

The power semiconductor device may include a well region having the second conductivity type and disposed on at least one side of the protrusion within the semiconductor layer, a source region having the first conductivity type and disposed in the well region and configured to contact a top surface of the semiconductor layer, and a well contact region having the second conductivity type and disposed at one side of the source region within the well region and configured to contact a top surface of the semiconductor layer.

The gate electrode layer may extend to cover a partial region of the source region while entirely covering the protrusion.

The gate electrode layer may include a plurality of sub-gate electrodes isolated from each other and configured to expose at least a portion of the protrusion.

The plurality of sub-gate electrodes may be disposed symmetrically with each other with respect to a center portion of the protrusion.

The semiconductor layer may include a drift region including impurities of the first conductivity type, the impurities being distributed at a first concentration and a junction field effect transistor (JFET) region including the impurities of the first conductivity type being distributed at a second concentration, the second concentration having a density greater than the first concentration, the JFET being disposed on the drift region.

The semiconductor layer further may include a first impurity region disposed in the JFET region and configured to have a third concentration of the first conductivity type and having a density greater than the second concentration.

The semiconductor layer may include a second impurity region including the third concentration of the first conductivity type disposed on at least one side of the first impurity region and arranged lower than the first impurity region by a height of the protrusion.

In a general aspect, here is provided a power semiconductor device including a semiconductor layer including silicon carbide (SiC), the semiconductor layer including a protrusion formed upwards from a partial portion of an upper region of the semiconductor layer, a gate insulation layer disposed on the semiconductor layer disposed to cover the protrusion, and including a region configured to contact a center portion of the protrusion having a first thickness greater than a second thickness of a region contacting both side surfaces of the protrusion, and a gate electrode layer disposed on the gate insulation layer.

In a general aspect, here is provided a power semiconductor device including a semiconductor layer including silicon carbide (SiC) having a first conductivity type, a shielding region having a second conductivity type opposite to the first conductivity type and disposed in the semiconductor layer so as to be in contact with a top surface of the semiconductor layer, a well region having the second conductivity type and disposed on at least one side of the shielding region in the semiconductor layer, a source region having the first conductivity type and disposed in the well region to contact a top surface of the semiconductor layer, a gate insulation layer disposed in the semiconductor layer and configured to cover the shielding region, and a gate electrode layer configured to cover the shielding region and disposed on the gate insulation layer and extending to the source region.

In a general aspect, here is provided a method of forming a semiconductor device including forming a semiconductor layer to include a protrusion formed outward from a partial portion of an upper region of the semiconductor layer, forming a shielding region within a central portion of an upper region of the protrusion, forming a gate electrode layer over the protrusion and the upper region of the semiconductor layer, and forming a gate insulation region to surround the gate electrode layer.

The semiconductor layer may include a first conductivity type and the shielding region may include a second conductivity type, different from the first conductivity type.

The forming of the semiconductor layer may include etching the semiconductor layer to form the protrusion and implanting impurities of a second conductivity type on one or more sides of the protrusion to form a well region.

The method may include implanting impurities of a first conductivity type in a well region to form a source region, the first conductivity type being different from the second conductivity type.

The method may include implanting impurities of the second conductivity type in the well region and the protrusion to form a well contact region and the shielding region.

A first concentration of the second conductivity type in the well contact region and the shielding region is greater than a second concentration of the second conductivity type in the well region.

The forming of the gate insulation region may include etching of the gate insulation region to expose a well contact region and a portion of a source region to form an upper gate insulation layer.

### BRIEF DESCRIPTION OF THE DRAWINGS

FIG. 1 is a cross-sectional view schematically showing a power semiconductor device according to one embodiment of the present disclosure.

FIGS. 2A to 2C are cross-sectional views schematically showing example processes of forming the structure of FIG. 1 according to one embodiment of the present disclosure.

FIG. 3 is a cross-sectional view showing a power semiconductor device according to another embodiment of the present disclosure.

FIGS. 4A and 4B are cross-sectional views schematically showing examples of a power semiconductor device according to other embodiments of the present disclosure.

FIG. 5 is a cross-sectional view schematically showing a power semiconductor device according to another embodiment of the present disclosure.

FIG. 6 is a cross-sectional view schematically showing a power semiconductor device according to another embodiment of the present disclosure.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Advantages and features of the present disclosure and methods of achieving the advantages and features will be clear with reference to embodiments described in detail below together with the accompanying drawings. However, the present disclosure is not limited to the embodiments disclosed herein but will be implemented in various forms. The embodiments of the present disclosure are provided so that the present disclosure is completely disclosed, and a person with ordinary skill in the art can fully understand the scope of the present disclosure. The present disclosure will be defined only by the scope of the appended claims. Meanwhile, the terms used in the present specification are for explaining the embodiments, not for limiting the present disclosure.

Terms, such as first, second, A, B, (a), (b) or the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween.

In a description of the embodiment, in a case in which any one element is described as being formed on or under another element, such a description includes both a case in which the two elements are formed in direct contact with each other and a case in which the two elements are in indirect contact with each other with one or more other elements interposed between the two elements. In addition, when one element is described as being formed on or under another element, such a description may include a case in which the one element is formed at an upper side or a lower side with respect to another element.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

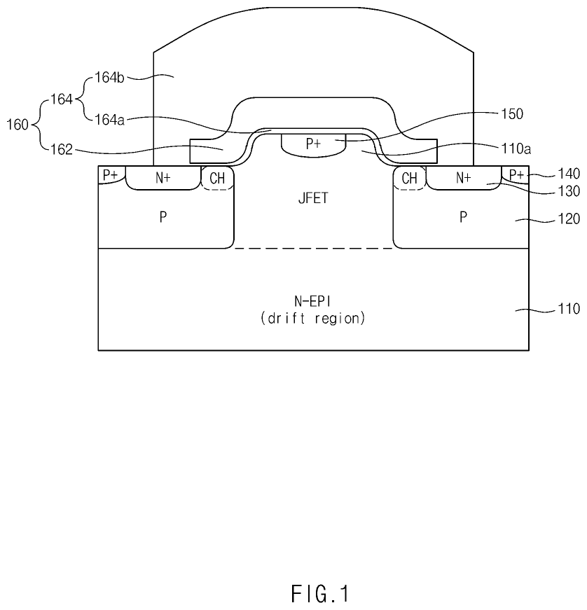

FIG. 1 is a cross-sectional view showing a power semiconductor device according to one embodiment of the present disclosure.

Referring to FIG. 1, the power semiconductor device may include a semiconductor layer 110, well region 120, source region 130, well contact region 140, a shielding region 150, and a gate 160.

The semiconductor layer 110 may include one or multiple semiconductor material layers. For example, the semiconductor layer 110 may include one or multiple epitaxial layers. The semiconductor layer 110 may include one or multiple epitaxial layers on a semiconductor substrate. For example, the semiconductor layer 110 may include a silicon carbide (SiC) substrate. Alternatively, the semiconductor layer 110 may include at least one SiC epitaxial layer in which the SiC substrate is grown. The semiconductor layer 110 may include a drift region into which impurities of the first conductivity type (e.g., N-type) are implanted. The semiconductor layer 110 may include an epitaxial layer formed of silicon carbide (SiC) (hereinafter referred to as ‘SiC epitaxial layer’) implanted with impurities of the first conductivity type (hereinafter referred to as ‘first conductive impurities’). The semiconductor layer 110 may provide a movement path of a current during operation of the power semiconductor device.

Silicon carbide (SiC) has a larger band gap than silicon (Si), so that the silicon carbide can maintain stability even at high temperature compared to silicon. Furthermore, silicon carbide (SiC) has a very high dielectric breakdown field compared to silicon, so that the silicon carbide can operate stably even at high voltage. Therefore, the power semiconductor device designed to use silicon carbide (SiC) as a semiconductor layer 110 has a higher breakdown voltage and more excellent heat dissipation characteristics than the other power semiconductor device in which silicon instead of silicon carbide is used, and can exhibit stable operation characteristics even at high temperature.

The semiconductor layer 110 may include a protrusion 110a protruding from a lower portion of the gate 160 to a predetermined height. For example, a top surface of the semiconductor layer 110 may have a stepped shape (i.e., a step) formed in a manner that a region between the well regions 120 in the semiconductor layer 110 protrudes farther upward than other regions. The length (width) of the protrusion 110a may be shorter than the length (width) of the gate electrode layer 162 such that the protrusion 110a can be covered by a gate electrode layer 162. In this case, an edge region of the protrusion 110a covered by the gate electrode layer 162 may be rounded to have a curvature. Particularly, a region (i.e., a stepped region) where a step is formed may be rounded to have a curvature.

A junction field effect transistor (JFET) region may be formed in an upper region of the semiconductor layer 110. For example, a JFET region for improving conduction characteristics may be formed as a charge storage structure in a region between adjacent well regions 120 in the semiconductor layer 110. The JFET region 180 may include the first conductivity-type impurities having a higher concentration than a region (i.e., a drift region) located under the JFET region 180. For example, the drift region may be distributed with impurities of the first conductivity type at a concentration of N−, and the JFET region may be distributed with impurities of the first conductivity type at a concentration of N.

Although FIG. 1 shows that the bottom surface of the JFET region is located at the same level as the bottom surface of the well region 120 for convenience of description, the scope or spirit of the present disclosure is not limited thereto.

A drain electrode (not shown) may be formed below the semiconductor layer 110. The drain electrode may include a conductive material such as metal.

When an operation voltage is applied to the gate electrode layer 162, the well region 120 may form a channel (CH) through which a current can flow between the JFET region of the semiconductor layer 110 and the source region 130. The well region 120 may be formed in the semiconductor layer 110 to be in contact with the top surface of the semiconductor layer 110. For example, the well region 120 may be located at both sides of the protrusion 110a in the semiconductor layer 110, and a portion of the well region 120 may be disposed below the gate to overlap the gate electrode layer 162 so that a channel (CH) can be formed in the corresponding region. The well region 120 may include impurities of a second conductivity type (e.g., P-type) opposite to the first conductivity type.

The source region 130 may be formed in the well region 120 to contact the top surface of the semiconductor layer 110. For example, the source region 130 may be located in the well region 120 such that a portion of the source region 130 can overlap both ends of the gate electrode 162. A partial region of the top surface of the source region 130 may be covered by the gate 160, and the other partial region of the top surface of the source region 130 may be exposed outside without being covered by the gate 160 so that the other partial region can contact the source electrode (not shown). The source region 130 may include the first conductivity-type impurities having a higher concentration than the semiconductor layer 110.

The well contact region 140 may be formed in the well region 120 to contact the top surface of the semiconductor layer 110. The well contact region 140 may be formed to be in contact with a source electrode (not shown), thereby supplying a source potential to the well region 120. The well contact region 140 may include impurities of the second conductivity type at a higher concentration than the well region 120.

The shielding region 150 may be formed to contact a gate insulation layer 164 within the protrusion 110a of the semiconductor layer 110. The shielding region 150 may be formed to cover a center portion of the gate insulation layer 164 within the protrusion 110a. The shielding region 150 may include impurities of the second conductivity type (i.e., P-type) having high concentration (P+).

Although FIG. 1 shows an example case in which the shielding region 150 covers only the center portion of the gate insulation layer 164 within the protrusion 110a for convenience of description, the scope or spirit of the present disclosure is not limited thereto, and it should be noted that the shielding region 150 entirely covers the top and side surfaces of the protrusion 110a. The shielding region 150 may be electrically connected to a source electrode (not shown) to receive a source potential.

The gate 160 may include the gate electrode layer 162 and the gate insulation layer 164. The gate electrode layer 162 may be formed over the semiconductor layer 110 to entirely cover the protrusion 110a. For example, the gate electrode layer 162 may be formed to extend to a length (width) that may cover some regions of the well regions 120 and the source regions 130 disposed at both sides of the protrusion 110a while entirely covering the protrusion 110a. The gate electrode layer 162 may form a horizontal channel (CH) in regions disposed below the gate electrode layer 162 upon receiving an operation voltage. The gate electrode layer 162 may include polysilicon or metal into which impurities are implanted.

The gate insulation layer 164 may be formed to surround the gate electrode layer 162. The gate insulation layer 134 may include a lower gate insulation layer 164a and an upper gate insulation layer 164b. The lower gate insulation layer 164a may represent a region formed between the gate electrode layer 162 and the semiconductor layer 110 in the gate insulation layer 164. The upper gate insulation layer 164b may represent a region that covers the top and side surfaces of the gate electrode layer 162 in the gate insulation layer 164. The gate insulation layer 164 may include an insulating material such as silicon oxide, silicon carbide oxide, silicon nitride, hafnium oxide, zirconium oxide, or aluminum oxide, or may include a stacked structure thereof.

A source electrode (not shown) may be formed on the semiconductor layer 110 and the gate 160 to contact the source region 130 and the well contact region 140.

When the operation voltage is applied to the gate electrode layer 162, an electric field may be concentrated at a lower surface of the gate electrode layer 162. When the electric field is concentrated at the lower surface of the gate electrode layer 162, the gate insulation layer 164 in the corresponding region is subjected to severe stress, which may cause dielectric breakdown of the gate insulation layer 164. Therefore, the lower surface of the gate insulation layer 164 may be surrounded by the impurity region (i.e., the shielding region) 150 of a type (i.e., P-type) opposite to the impurity type (N-type) of the semiconductor layer 120, thereby preventing dielectric breakdown of the gate insulation layer 164.

However, when the top surface of the semiconductor layer 110 is planarized and the shielding region is formed by implanting high-concentration impurities of the second conductivity type into a lower portion of the gate insulation layer, the shielding region may interfere with the flow of a current.

In the present embodiment, after the semiconductor layer 110 formed between the well regions 120 protrudes upward to a predetermined height, the shielding region 150 is formed at the protrusion portion 110a so that the flow of current can be facilitated and dielectric breakdown of the gate insulation layer 164 can be prevented.

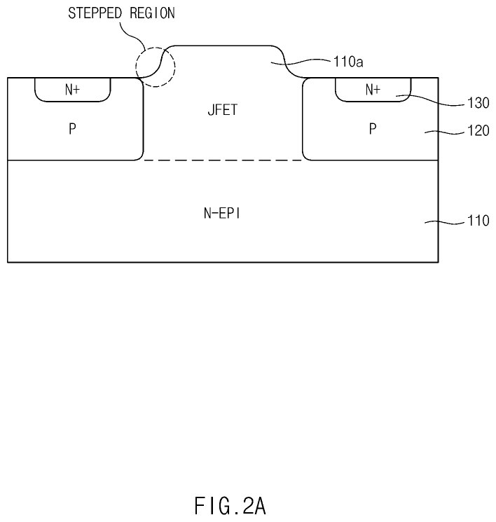

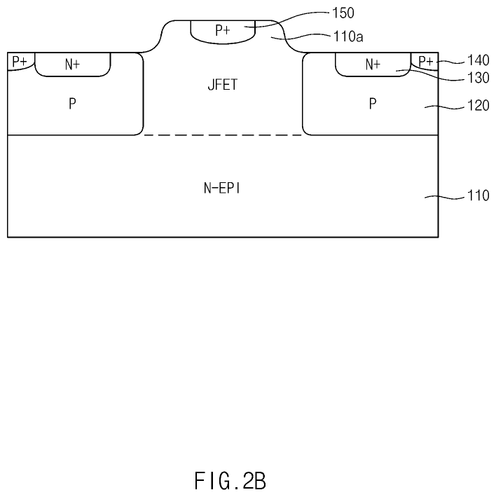

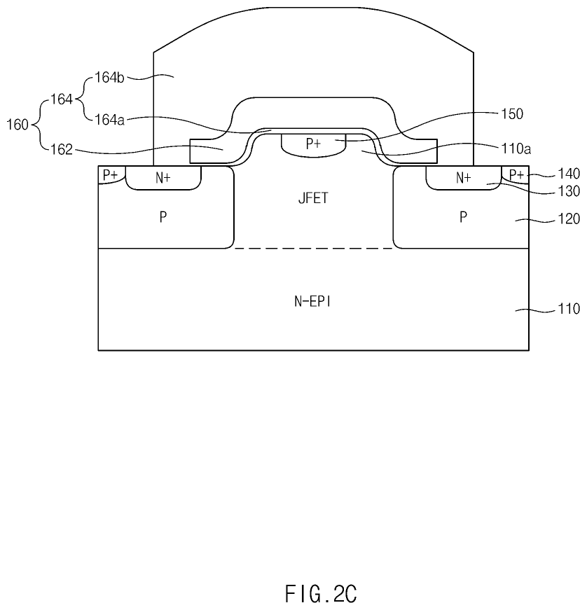

FIGS. 2A to 2C are cross-sectional views schematically showing example processes of forming the structure of FIG. 1 according to one embodiment of the present disclosure.

Referring to FIG. 2A, a portion of an upper region of the semiconductor layer 110 may be partially etched to form a protrusion 110a in which an unetched region of the semiconductor layer 110 protrudes upward. For example, the protrusion 110a may be formed in the semiconductor layer 110 between the adjacent well regions 120 by etching a region where the well region 120 is to be formed in a subsequent process.

In this case, the protrusion 110a may be formed through a key etch process or a trench etch process so that a region (i.e., a stepped region) where a stepped shape is formed at the top surface of the semiconductor layer 110 has a curvature.

Subsequently, the well region 120 may be formed by implanting impurities of the second conductivity type into both sides of the protrusion 110a, and impurities of the first conductivity type may be implanted into the upper region of the well region 120 to form the source region 130.

In a region between adjacent well regions 120 in the semiconductor layer 110, a JFET region in which impurities of the first conductivity type are implanted with a higher concentration than an underlying region (i.e., a drift region) can be formed. The JFET region may be formed before or after the well region 120 is formed.

Referring next to FIG. 2B, the shielding region 150 and the well contact region 140 may be formed by implanting high-concentration impurities (P+-type impurities) of the second conductivity type into the protrusion 110a and the well region 120. For example, the shielding region 150 may be formed at the center portion of the protrusion 110a to contact the top surface of the protrusion 110a, and the well contact region 140 may be formed next to the source region 130 so as to be in contact with the top surface of the semiconductor layer 110.

Subsequently, a thermal annealing process may be performed on the semiconductor layer 110 in which the impurity regions (120, 130, 140, 150) are formed, so that the implanted impurities can be activated.

Referring to FIG. 2C, a gate 160 may be formed on the semiconductor layer 110a including the protrusion 110a.

For example, after an insulation layer is formed on the semiconductor layer 110a and a conductive material for the gate (hereinafter referred to as a gate conductive material) is formed on the insulation layer, the gate conductive material may be patterned, resulting in formation of the gate electrode layer 162. In this case, the insulation layer formed below the gate electrode layer 162 may be used as a lower gate insulation layer 164a.

Subsequently, after the insulation layer is formed entirely over the gate electrode layer 162 and the semiconductor layer 110, the insulation layer may be patterned to expose the well contact region 140 and a portion of the source region 130, resulting in formation of an upper gate insulation layer 164b.

Then, a source electrode (not shown) may be formed on the semiconductor layer 110 and the gate 160 to contact the source region 130 and the well contact region 140, and a drain electrode (not shown) may be formed below the semiconductor layer 110.

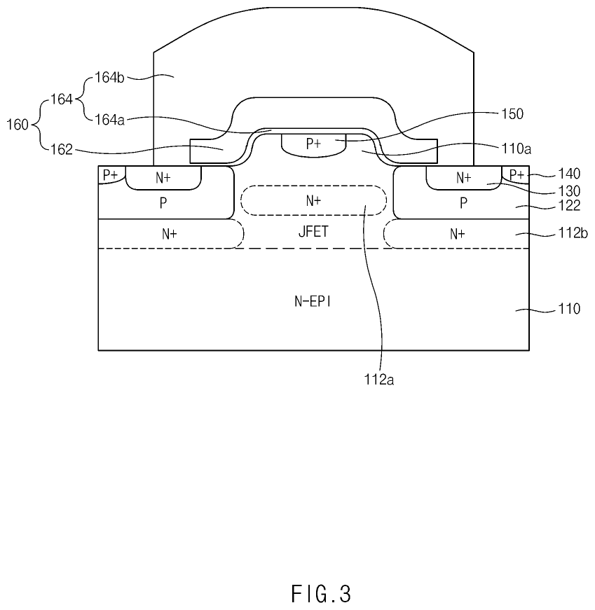

FIG. 3 is a cross-sectional view showing a power semiconductor device according to another embodiment of the present disclosure.

Referring to FIG. 3, in the power semiconductor device according to the present embodiment, impurities of the first conductivity type are additionally implanted into the semiconductor layer 110 in a stepwise manner, so that a high-concentration impurity region 112 can be formed in a stepped shape.

For example, impurities of the first conductivity type are implanted into the lower region of the well region 122 and the JFET region to form the impurity regions 112a and 112b, such that the depth of the well region 122 can be reduced and ON-resistance (Rdson) of the JFET region can also be reduced. Each of the impurity regions 112a and 112b may have a higher N+ concentration than the JFET region.

In the present embodiment, a portion of the upper region of the semiconductor layer 110 protrudes upward such that the top surface of the semiconductor layer 110 can be formed in a stepped shape. As a result, when the first conductivity-type impurities are implanted into the entire top surface of the stepped semiconductor layer 110 under the same conditions, the impurity regions 112a and 112b can be formed in a stepped shape as shown in FIG. 3. For example, the impurity region 112b disposed below the well region 122 may be formed at a lower position than the impurity region 112a formed in the JFET region by a height of the protrusion 110a.

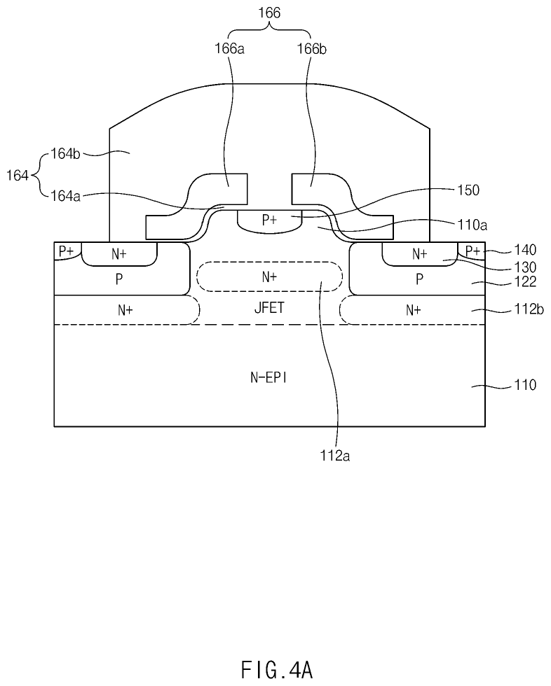

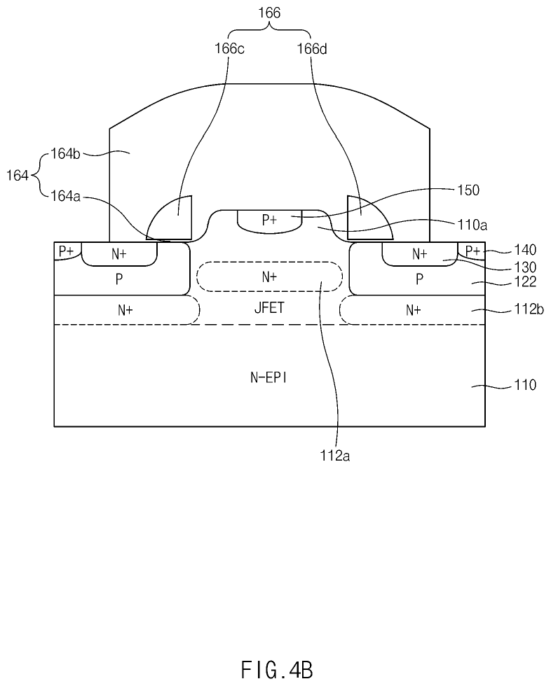

FIGS. 4A and 4B are cross-sectional views schematically showing examples of a power semiconductor device according to other embodiments of the present disclosure.

Referring to FIGS. 4A and 4B, the power semiconductor device according to the present embodiment may include a gate electrode layer 166 that exposes at least a portion of the protrusion 110a without covering the portion of the protrusion 110a. For example, the gate electrode layer 166 may include a plurality of sub-gate electrodes (166a, 166b) isolated from each other such that a partial region (i.e., a center portion) of the top surface of the protrusion 110a is exposed as shown in FIG. 4A, or may include a plurality of sub-gate electrodes (166c, 166d) isolated from each other such that the entire top surface of the protrusion 110a is exposed as shown in FIG. 4B.

The isolated sub-gate electrodes (166a-166b or 166c-166d) may be located symmetrical to each other with respect to the center of the protrusion 110a. The distance between the isolated sub-gate electrodes (166a-166b or 166c-166d) may be adjusted as needed.

As such, since the gate electrode layers 166 are isolated from each other such that a conductive material is not formed in at least a portion of the protrusion 110a, capacitance to be generated by the conductive material can be controlled.

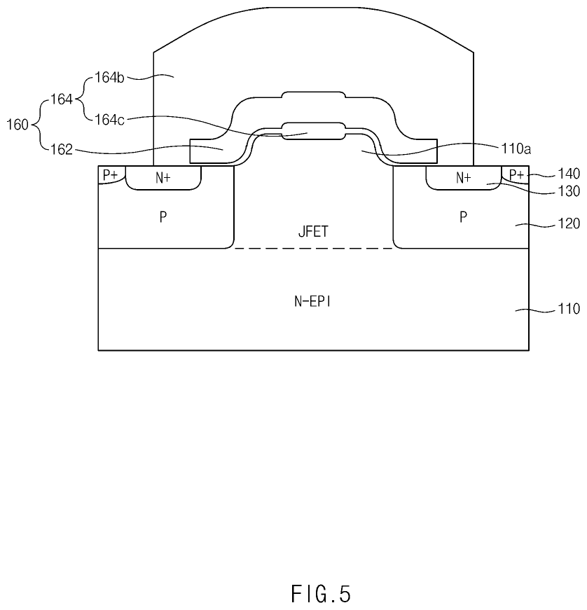

FIG. 5 is a cross-sectional view schematically showing a power semiconductor device according to another embodiment of the present disclosure.

Referring to FIG. 5, the power semiconductor device according to the present embodiment may include a gate insulation layer 164c formed to be partially thick. For example, instead of forming the shielding region 150, the gate insulation layer 164c of the corresponding region is formed relatively thick, thereby preventing dielectric breakdown of the gate insulation layer 164 from being easily generated in the corresponding region.

In the power semiconductor device of FIG. 5, impurity regions (112a, 112b) may be formed to be stepped as in the above-described embodiment of FIG. 3. Also, as in the embodiment of FIG. 4A or 4B, the gate electrode layer 162 may be formed to be isolated from other layers.

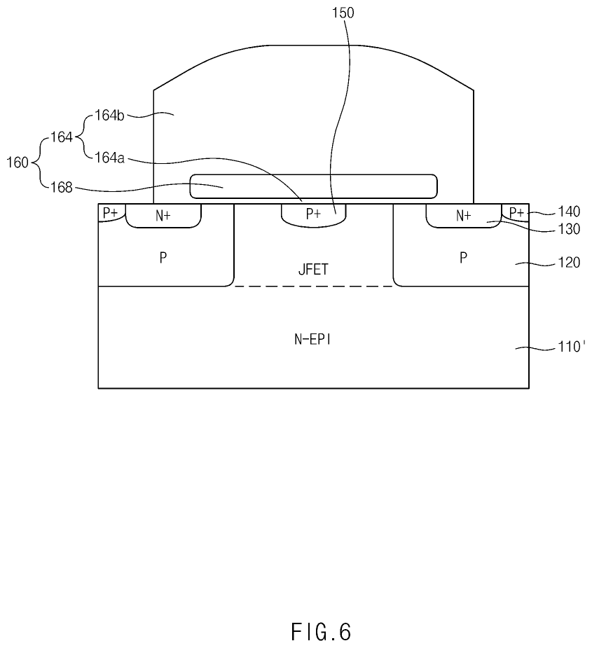

FIG. 6 is a cross-sectional view schematically showing a power semiconductor device according to another embodiment of the present disclosure.

Referring to FIG. 6, unlike the above-described embodiments, the power semiconductor device according to the present embodiment may include a shielding region 150 that is disposed below the gate insulation layer 164a such that the shielding region 150 can contact the gate insulation layer 164a in a state in which a protrusion is not formed on the semiconductor layer 110′.

In the power semiconductor device of FIG. 6, impurity regions (112a, 112b) may be formed to be stepped as in the above-described embodiment of FIG. 3. Also, as in the embodiment of FIG. 4A or 4B, the gate electrode layer 162 may be formed to be isolated from other layers.

As is apparent from the above description, the power semiconductor device according to the embodiments of the present disclosure can stably protect a lower portion of a gate by mitigating concentration of an electric field applied to the lower portion of the gate while increasing mobility.

Various embodiments of the present disclosure do not list all available combinations but are for describing a representative aspect of the present disclosure, and descriptions of various embodiments may be applied independently or may be applied through a combination of two or more.

A number of embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power semiconductor device, comprising:
a semiconductor layer having a first conductivity type and configured to include a protrusion formed from an upper region of the semiconductor layer to partially protrude upward;
a shielding region, having a second conductivity type opposite to the first conductivity type, disposed within the protrusion, and configured to contact a top surface of the protrusion;
a gate insulation layer disposed on the semiconductor layer and configured to cover the protrusion and to be in contact with the shielding region; and
a gate electrode layer disposed on the gate insulation layer.

2. The power semiconductor device according to claim 1, further comprising:
a well region having the second conductivity type and disposed on at least one side of the protrusion within the semiconductor layer;
a source region having the first conductivity type and disposed in the well region and configured to contact a top surface of the semiconductor layer; and
a well contact region having the second conductivity type and disposed at one side of the source region within the well region and configured to contact a top surface of the semiconductor layer.

3. The power semiconductor device according to claim 2, wherein:
the gate electrode layer extends to cover a partial region of the source region while entirely covering the protrusion.

4. The power semiconductor device according to claim 2, wherein the gate electrode layer comprises:
a plurality of sub-gate electrodes isolated from each other and configured to expose at least a portion of the protrusion.

5. The power semiconductor device according to claim 4, wherein:
the plurality of sub-gate electrodes are disposed symmetrically with each other with respect to a center portion of the protrusion.

6. The power semiconductor device according to claim 1, wherein the semiconductor layer comprises:
a drift region comprising impurities of the first conductivity type, the impurities being distributed at a first concentration; and
a junction field effect transistor (JFET) region comprising the impurities of the first conductivity type being distributed at a second concentration, the second concentration having a density greater than the first concentration, the JFET being disposed on the drift region.

7. The power semiconductor device according to claim 6, wherein the semiconductor layer further comprises:
a first impurity region disposed in the JFET region and configured to have a third concentration of the first conductivity type and having a density greater than the second concentration.

8. The power semiconductor device according to claim 7, wherein the semiconductor layer further comprises:
a second impurity region including the third concentration of the first conductivity type disposed on at least one side of the first impurity region and arranged lower than the first impurity region by a height of the protrusion.

9. A power semiconductor device, comprising:
a semiconductor layer comprising silicon carbide (SiC), the semiconductor layer including a protrusion formed upwards from a partial portion of an upper region of the semiconductor layer;
a gate insulation layer disposed on the semiconductor layer disposed to cover the protrusion, and comprising a region configured to contact a center portion of the protrusion having a first thickness greater than a second thickness of a region contacting both side surfaces of the protrusion; and
a gate electrode layer disposed on the gate insulation layer.

10. A power semiconductor device, comprising:
a semiconductor layer comprising silicon carbide (SiC) having a first conductivity type;
a shielding region having a second conductivity type opposite to the first conductivity type and disposed in the semiconductor layer so as to be in contact with a top surface of the semiconductor layer;
a well region having the second conductivity type and disposed on at least one side of the shielding region in the semiconductor layer;
a source region having the first conductivity type and disposed in the well region to contact a top surface of the semiconductor layer;
a gate insulation layer disposed in the semiconductor layer and configured to cover the shielding region; and
a gate electrode layer configured to cover the shielding region and disposed on the gate insulation layer and extending to the source region.

11. A method of forming a semiconductor device, the method comprising:
forming a semiconductor layer to include a protrusion formed outward from a partial portion of an upper region of the semiconductor layer;
forming a shielding region within a central portion of an upper region of the protrusion;
forming a gate electrode layer over the protrusion and the upper region of the semiconductor layer; and
forming a gate insulation region to surround the gate electrode layer.

12. The method of claim 11, wherein the semiconductor layer comprises a first conductivity type, and
wherein the shielding region comprises a second conductivity type, different from the first conductivity type.

13. The method of claim 11, wherein the forming of the semiconductor layer comprises:
etching the semiconductor layer to form the protrusion; and
implanting impurities of a second conductivity type on one or more sides of the protrusion to form a well region.

14. The method of claim 13, further comprising:
implanting impurities of a first conductivity type in a well region to form a source region, the first conductivity type being different from the second conductivity type.

15. The method of claim 13, further comprising:
implanting impurities of the second conductivity type in the well region and the protrusion to form a well contact region and the shielding region.

16. The method of claim 15, wherein a first concentration of the second conductivity type in the well contact region and the shielding region is greater than a second concentration of the second conductivity type in the well region.

17. The method of claim 13, wherein the forming of the gate insulation region comprises:
etching of the gate insulation region to expose a well contact region and a portion of a source region to form an upper gate insulation layer.
